(19) United States
(12) Patent Application Publication
(10) Pub. No.: US 2025/0233023 A1
(43) Pub. Date: Jul. 17, 2025

(54) PLASMA PROCESSING APPARATUS, PLASMA PROCESSING METHOD, AND WAFER PROCESSING METHOD

(71) Applicant: Samsung Electronics Co., Ltd., Suwon-si (KR)

(72) Inventors: Jewon Lee, Suwon-si (KR); Sunghoon Hwang, Suwon-si (KR)

(21) Appl. No.: 18/967,533

(22) Filed: Dec. 3, 2024

(30) Foreign Application Priority Data
Jan. 15, 2024 (KR) 10-2024-0006103

(51) Int. Cl. H01L 21/66; H01J 37/32

(52) U.S. Cl. CPC H01L 22/12; H01J 37/32935; H01J 2237/24585; H01J 2237/334

(57) ABSTRACT

A wafer processing includes performing a process on the wafer, wherein the performing of the process on the wafer includes receiving a temperature profile and a heater profile, the temperature profile and the heater profile forming a pair with each other, calculating a combination profile based on the temperature profile and the heater profile, outputting a final profile based on the combination profile, and performing wafer processing by using a plasma based on the final profile.

### CROSS-REFERENCE TO RELATED APPLICATION

This application is based on and claims priority under 35 U.S.C. § 119 to Korean Patent Application No. 10-2024-0006103, filed on Jan. 15, 2024, in the Korean Intellectual Property Office, the disclosure of which is incorporated by reference herein in its entirety.

### BACKGROUND

Embodiments of the inventive concept relate to a plasma processing apparatus, a plasma processing method, and a wafer processing method, and more particularly, to a plasma processing apparatus capable of improving distribution defects in an etching process, a plasma processing method, and a wafer processing method.

In general, semiconductor devices are manufactured through multiple unit processes including a deposition process of a thin film and an etching process, and the etching process is mainly performed in a semiconductor manufacturing facility where a plasma reaction is induced. As semiconductor products are miniaturized and highly integrated, the influence of distribution defects in an etching process on the characteristics of semiconductor products has increased.

### SUMMARY

Embodiments of the inventive concept provide a plasma processing apparatus that may improve distribution defects in an etching process, a plasma processing method, and a wafer processing method.

In addition, objects of the inventive concept are not limited to the objects mentioned above, and other objects may be clearly understood by those skilled in the art from the description below.

According to an aspect of the inventive concept, there is provided wafer processing method including performing a process on the wafer, wherein the performing of the process on the wafer includes receiving a temperature profile and a heater profile, the temperature profile and the heater profile forming a pair with each other, calculating a combination profile based on the temperature profile and the heater profile, outputting a final profile based on the combination profile, and performing wafer processing by using a plasma based on the final profile.

According to another aspect of the inventive concept, there is provided a wafer processing method including performing a process on the wafer, wherein the performing of the process on the wafer includes receiving a temperature profile and a heater profile, the temperature profile and the heater profile forming a pair with each other, calculating a first heater profile and a second heater profile based on the temperature profile and the heater profile, calculating a combination profile based on the first heater profile and the second heater profile, outputting a final profile based on the combination profile, and performing wafer processing by using a plasma based on the final profile, wherein the second heater profile is calculated based on feedback control.

According to another aspect of the inventive concept, there is provided a wafer processing method including preparing a wafer, and performing a process on the wafer, wherein the performing of the process on the wafer includes receiving a temperature profile and a heater profile, the temperature profile and the heater profile forming a pair with each other, calculating a combination profile based on the temperature profile and the heater profile, and outputting a final profile based on the combination profile.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view of a plasma processing apparatus according to an embodiment;

FIG. 2 is a block diagram illustrating a plasma processing method according to an embodiment;

FIG. 3 is a flowchart illustrating a plasma processing method according to an embodiment;

FIG. 4 is a flowchart illustrating a method of generating a combination profile according to an embodiment;

FIG. 5 is a graph showing a temperature profile according to an embodiment;

FIG. 6 is a graph showing the temperature for each wafer according to a comparative example;

FIG. 7 is a graph showing the temperature for each wafer according to an embodiment; and

FIG. 8 is a flowchart illustrating a wafer processing method according to an embodiment.

### DETAILED DESCRIPTION OF THE EMBODIMENTS

The inventive concept will now be described more fully with reference to the accompanying drawings, in which embodiments of the inventive concept are shown. Like reference numerals in the drawings denote like elements, and thus their description will be omitted. In the following drawings, thicknesses or sizes of each layer are exaggerated for convenience of explanation, and thus the thicknesses or sizes of each layer may slightly differ from the actual shapes and proportions. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

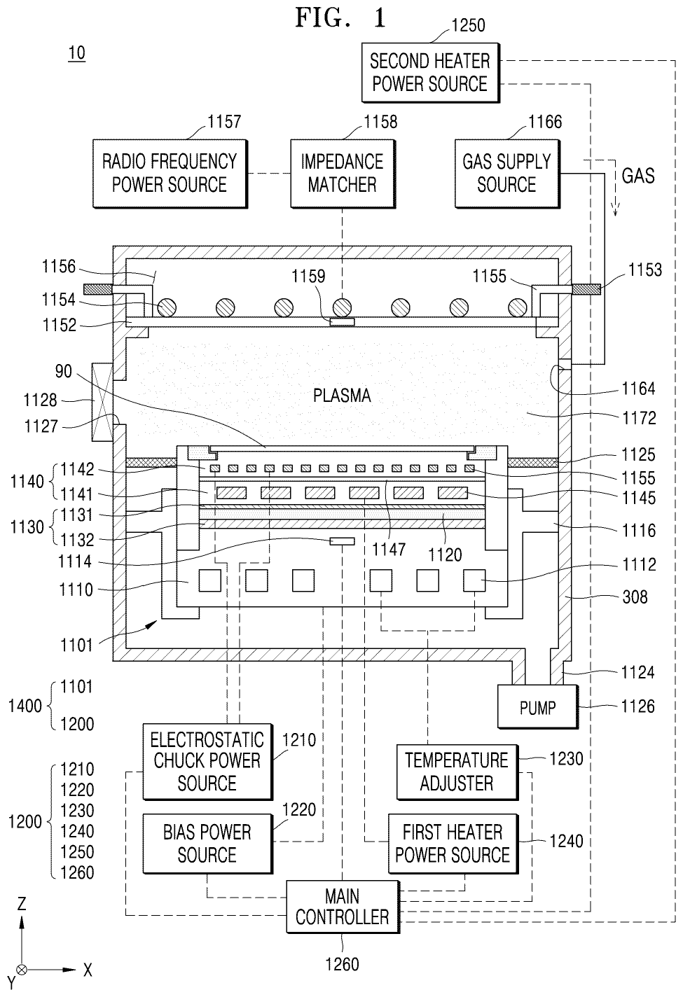

FIG. 1 is a cross-sectional view of a plasma processing apparatus according to an embodiment.

Referring to FIG. 1, a plasma processing apparatus 10 may perform etching processing on a wafer 90 mounted on an electrostatic chuck (ESC) 1101 by using an inductively-coupled plasma (ICP) generated by an inductively-coupled-type method. In another embodiment, the electrostatic chuck 1101 may also be used in an etching processing apparatus using a charge-coupled plasma (CCP) generated by a charged-coupled-type method.

The plasma processing apparatus 10 may include an electrostatic chuck assembly 1400 including the static chuck 1101, on which the wafer 90 is mounted, in the lower center of a process chamber 308 in a cylindrical shape. The electrostatic chuck assembly 1400 may include the electrostatic chuck 1101 that adsorbs the wafer 90, for example, a silicon wafer, and a control part 1200 that controls the operations of the components of the plasma processing apparatus 10.

The electrostatic chuck 1101 may include a base 1110 and a dielectric laminate 1140 adhered to the base 1110 by an adhesive layer 1130. The dielectric laminate 1140 may include a heater dielectric layer 1141 and an electrostatic dielectric layer 1142, which are sequentially stacked on the base 1110.

The adhesive layer 1130 may have a double film structure including a first adhesive 1131 and a second adhesive 1132. A metal plate 1120 may be further provided between the first adhesive 1131 and the second adhesive 1132. The base 1110 may have a circular shape or a disk shape, which is configured to comprise a metal, for example, aluminum (Al), titanium (Ti), stainless steel, tungsten (W), or alloys thereof.

The electrostatic chuck 1101 may be used in the plasma processing apparatus 10 that performs etching processing on the wafer 90 by using plasma. In this case, the interior of the process chamber 308 in which the electrostatic chuck 1101 is installed is formed as a high-temperature environment, and when the wafer 90 is exposed to high-temperature plasma, damage, such as ion bombardment, may occur on the wafer 90. To prevent damage to the wafer 90 and perform uniform plasma processing, the wafer 90 may need to be cooled.

To cool the wafer 90, a coolant channel 1112 may be further provided in the base 1110. For example, the coolant may include water, ethylene glycol, silicone oil, liquid Teflon, and a mixture of water and glycol. The coolant channel 1112 may have a concentrical or helical pipe structure around the central axis of the base 1110.

The coolant channel 1112 may include an inlet where a coolant is introduced and an outlet where the coolant is discharged, and the inlet and the outlet may be connected to a temperature adjuster 1230 of the control part 1200. The flow rate and temperature of the coolant circulating in the coolant channel 1112 may be adjusted by the temperature adjuster 1230.

The base 1110 may be electrically connected to a bias power source 1220 of the control part 1200. A high frequency or radio frequency may be applied to the base 1110 from the bias power source 1220, and thus the base 1110 may serve as an electrode for the generation of plasma.

The base 1110 may further include a first temperature sensor 1114. The first temperature sensor 1114 may transmit a measured temperature of the base 1110 to a main controller 1260 of the control part 1200. Based on the measured temperature from the first temperature sensor 1114, the temperature of the electrostatic chuck 1101, for example, the temperature of the electrostatic dielectric layer 1150 or the wafer 90, may be predicted.

The heater dielectric layer 1141 may include an embedded heater electrode 1145. The heater dielectric layer 1141 may include a dielectric, such as ceramic, for example, an aluminum oxide (Al₂O₃) layer, an aluminum nitride (AlN) layer, a yttrium oxide (Y₂O₃) layer, or resin, such as polyimide. The heater dielectric layer 1141 may have a circular shape or a disc shape.

The heater electrode 1145 may include a conductor, for example, a metal such as tungsten (W), copper (Cu), nickel (Ni), molybdenum (Mo), titanium (Ti), a nickel-chromium (Ni—Cr) alloy, a nickel-aluminum (Ni—Al) alloy, or the like, or a conductive ceramic such as tungsten carbide (WC), molybdenum carbide (MoC), titanium nitride (TiN), or the like.

The heater electrode 1145 may be electrically connected to a first heater power source 1240 of the control part 1200. The heater electrode 1145 may be heated by power from the first heater power source 1240, for example, an alternating voltage, so that the temperature of the electrostatic chuck 1101 or the wafer 90 may be adjusted. The heater electrode 1145 may have a concentrical shape or a helical shape with respect to the central axis of the heater dielectric layer 1141.

An embedded adsorption electrode 1155 may be installed in the electrostatic dielectric layer 1142. The adsorption electrode 1155 may also be referred to as a clamp electrode. The electrostatic dielectric layer 1142 may include a dielectric, such as ceramic, for example, an aluminum oxide (Al₂O₃) layer, an aluminum nitride (AlN) layer, a yttrium oxide (Y₂O₃) layer, or resin, such as polyimide. The electrostatic dielectric layer 1142 may have a circular shape or a disc shape.

The wafer 90 may be arranged on the electrostatic dielectric layer 1142. The adsorption electrode 1155 may include a conductor, for example, a metal, such as tungsten (W), copper (Cu), nickel (Ni), molybdenum (Mo), a nickel-chromium (Ni—Cr) alloy, a nickel-aluminum (Ni—Al) alloy, or the like, or a conductive ceramic, such as tungsten carbide (WC), molybdenum carbide (MoC), titanium nitride (TiN), or the like.

The adsorption electrode 1155 may be electrically connected to an electrostatic chuck (ESC) power source 1210 of the control part 1200. An electrostatic force may be generated between the adsorption electrode 1155 and the wafer 90 by the power applied from the ESC power source 1210, for example, a direct current voltage, so that the wafer 90 may be adsorbed on the electrostatic dielectric layer 1142. The adsorption electrode 1155 may include a plurality of sub-adsorption electrodes positioned in the electrostatic dielectric layer 1142 and spaced apart from each other.

The dielectric laminate 1140 may selectively further include a heat distribution layer 1147 provided between the heater dielectric layer 1141 and the electrostatic dielectric layer 1142. The heat distribution layer 1147 may include, for example, an aluminum nitride (AlN) layer, a boron nitride (BN) layer, a tungsten (W) layer, a molybdenum (Mo) layer, or the like, which has a thermal conductivity of about 10 W/mK or more. The heat distribution layer 1147 may further uniformly distribute heat generated by the heater electrode 1145.

The electrostatic chuck 1101 may have a staircase structure suitable for applying a generally uniform electric field to the wafer 90. The electrostatic dielectric layer 1142 may be coupled to the heater dielectric layer 1141 without the help of an adhesive layer. The heater dielectric layer 1141 may be coupled to the base 1110 by the adhesive layer 1130 having a double-film layer.

The electrostatic chuck 1101 may be supported by a support portion 1116 fixed on the inner side wall of the process chamber 308. A baffle plate 1125 may be provided between the electrostatic chuck 1101 and the inner side wall of the process chamber 308. An exhaust pipe 1124 may be provided on a lower portion of the process chamber 308, and the exhaust pipe 1124 may be connected to a vacuum pump 1126. A gate valve 1128 opening and closing an opening 1127 via which the wafer may enter or exit the process chamber 308 may be provided on the outer wall of the process chamber 308.

A dielectric window 1152 spaced apart from the electrostatic chuck 1101 may be provided on the ceiling of the process chamber 308. An antenna room 1156 accommodating a radio frequency antenna 1154 in a helical or concentrical coil shape may be installed integrally with the process chamber 308 on the dielectric window 1152. The radio frequency antenna 1154 may be electrically connected to a radio frequency (RF) power source 1157 for plasma generation through an impedance matcher 1158. The RF power source 1157 may output radio frequency power suitable for plasma generation. The impedance matcher 1158 may be provided for matching the impedance and load of the RF power source 1157, for example, the impedance of the radio frequency antenna 1154.

An upper heater 1153 may be arranged outside the antenna room 1156. The upper heater 1153 may be electrically connected to a second heater power source 1250 of the control part 1200. The upper heater 1153 may be heated by power from the second heater power source 1250, for example, an alternating voltage, so that the temperature of the dielectric window 1152 may be adjusted. The upper heater 1153 may heat the dielectric window 1152 in an air-heating method. For example, the upper heater 1153 may be spaced apart from the dielectric window 1152 in a vertical direction (Z direction). Heat generated by the upper heater 1153 may be supplied to the dielectric window 1152 through a heating channel 1151. For example, air may be arranged in the heating channel 1151. That is, the upper heater 1153 may heat the air inside the heating channel 1151 to indirectly heat the dielectric window 1152.

For example, the upper heater 1153 may include a conductor, for example, a metal, such as tungsten (W), copper (Cu), nickel (Ni), molybdenum (Mo), titanium (Ti), a nickel-chromium (Ni—Cr) alloy, and/or a nickel-aluminum (Ni—Al) alloy, or the like, or a conductive ceramic, such as tungsten carbide (WC), molybdenum carbide (MoC), and/or titanium nitride (TiN), or the like.

Herein, a direction parallel to the main surface of the wafer 90 may be defined as a horizontal direction (X direction and/or Y direction), and a direction perpendicular to the horizontal direction (X direction and/or Y direction) may be defined as a vertical direction (Z direction).

A second temperature sensor 1159 may be arranged inside the dielectric window 1152. The second temperature sensor 1159 may transmit a measured temperature of the dielectric window 1152 to the main controller 1260 of the control part 1200. The temperature of the dielectric window 1152 may be predicted based on the measured temperature from the second temperature sensor 1159.

FIG. 1 shows that the second temperature sensor 1159 is arranged inside the dielectric window 1152, but embodiments of the inventive concept are not limited thereto. For example, the second temperature sensor 1159 may be arranged to be spaced apart from the dielectric window 1152.

The ESC power source 1210, the bias power source 1220, the temperature adjuster 1230, the first heater power source 1240, and the second heater power source 1250 may be controlled by the main controller 1260. For example, based on the measured temperature from the first temperature sensor 1114, the main controller 1260 may read the temperature of the electrostatic chuck 1101 or the wafer 90 and adjust power of the first heater power source 1240 to adjust the amount of heat generated from the heater electrode 1145. Accordingly, the temperature of the electrostatic chuck 1101 or the wafer 90 may be appropriately controlled.

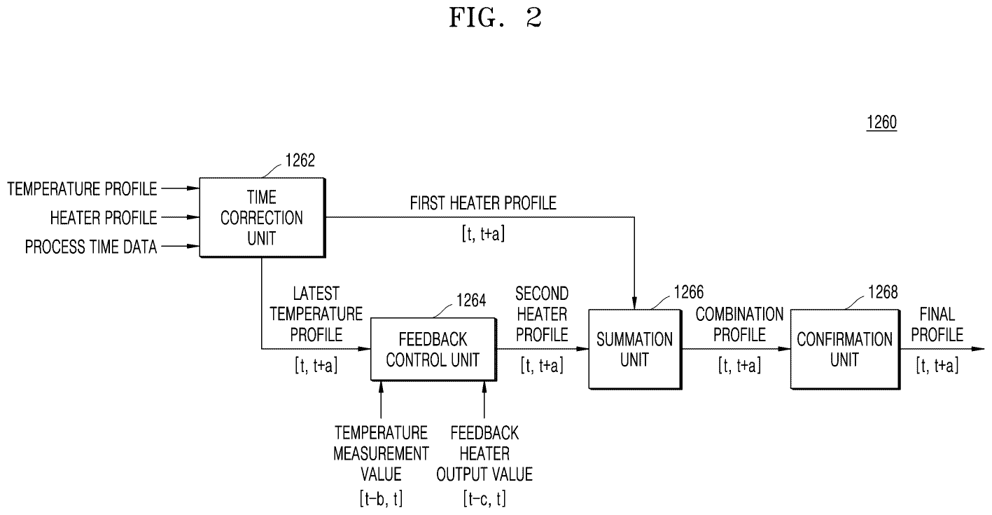

In a similar way, based on the measured temperature from the second temperature sensor 1159, the main controller 1260 may read the temperature of the dielectric window 1152 and adjust power of the second heater power source 1250 to adjust the amount of heat generated from the upper heater 1153. Accordingly, the temperature of each processing room 1172 may be appropriately controlled. A method in which the main controller 1260 controls the second heater power source 1250 based on the temperature of the dielectric window 1152 is further described in detail below with reference to FIGS. 2 to 5.

The control part 1200 may be implemented as hardware, firmware, software, or any combination thereof. For example, the control part 1200 may be a computing apparatus, such as a workstation computer, a desktop computer, a laptop computer, a tablet computer, or the like. For example, the control part 1200 may include a memory device, such as read-only memory (ROM), random-access memory (RAM),or the like, and a processor configured to perform certain operations and algorithms, for example, a microprocessor, a central processing unit (CPU), a graphics processing unit (GPU), or the like. In addition, the control part 1200 may include a receiver and a transmitter, which are respectively configured to receive and transmit electrical signals.

A gas supply source 1166 may supply a processing gas, for example, an etching gas, to the process chamber 308 through a supply device 1164, such as a nozzle or a porthole installed on a side wall of the process chamber 308. To perform etching processing, the gate valve 1128 may be opened to load (or mount) the wafer 90 on the electrostatic chuck 1101 within the process chamber 308. The wafer 90 may be adsorbed to the electrostatic chuck 1101 by an electrostatic force generated by applying power to the electrostatic chuck 1101 from the ESC power source 1210.

An etching gas from the gas supply source 1166 may be introduced to the process chamber 308. At this time, the pressure in the process chamber 308 may be set to a fixed value by the vacuum pump 1126. Power from the RF power source 1157 may be applied to the radio frequency antenna 1154 via the impedance matcher 1158. In addition, power from the bias power source 1220 may be applied to the base 1110.

The etching gas introduced to the process chamber 308 may be generally uniformly spread in the processing room 1172 below the dielectric window 1152. A magnetic field may be generated around the radio frequency antenna 1154 by a current flowing in the radio frequency antenna 1154, and a magnetic line may pass through the processing room 1172 by penetrating or extending through the dielectric window 1152. An induced electric field may be generated by the temporal change of the magnetic field, and electrons accelerated by the induced electric field may collide with the molecules or atoms of the etching gas to generate plasma.

As such, ions of the plasma may be supplied to the wafer 90 by using a plasma generation unit, so that wafer processing, that is, etching processing, may be performed in a processing room. The plasma generation unit may include the gas supply source 1166 that supplies a processing gas to the processing room 1172, an antenna 1154 provided in the antenna room 1156, and an RF power source 1157 that provides RF power to the antenna 1154.

Unlike the heater electrode 1145, the upper heater 1153 may be spaced apart from an object for temperature control (e.g., the dielectric window 1152) to heat the object for temperature control in an air-heating method. Accordingly, the heating of the dielectric window 1152 by the upper heater 1153 may require a relatively longer reaction time, which may make it difficult for the second heater power source 1250 to control the temperature of the object for temperature control. Therefore, a method of controlling the temperature of the dielectric window 1152 by using the second heater power source 1250 may be desired.

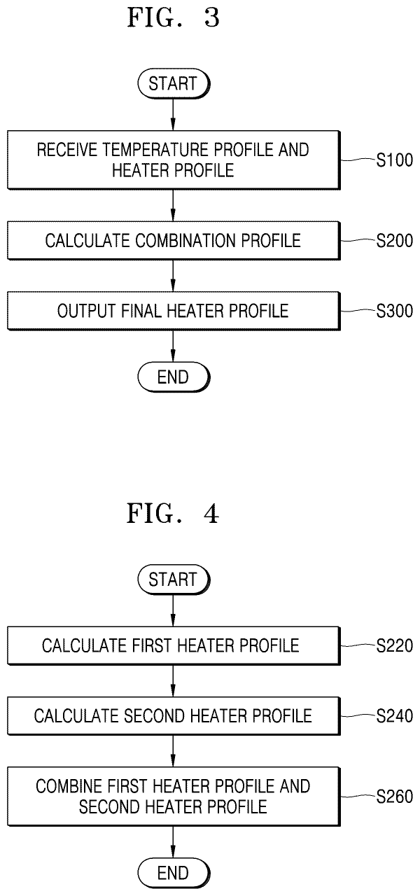

FIG. 2 is a block diagram illustrating a plasma processing method according to an embodiment, and FIG. 3 is a flowchart illustrating a plasma processing method according to an embodiment. In FIG. 2, the information shown below each piece of data indicates the time domain of each piece of data. For example, [t, t+a] represents the time domain from t to t+a, and [t−b, t] represents the time domain from t−b to t. In addition, [t−c, t] represents the time domain from t−c to t. That is, [t, t+a] may include the future, and [t−b, t] and [t−c, t] may include the past. The description is made with reference to FIG. 1.

Referring to FIGS. 2 and 3, the main controller 1260 may include a time correction unit 1262, a feedback control unit 1264, a summation unit 1266, and a confirmation unit 1268. FIG. 2 illustrates that the main controller 1260 includes four different devices, but embodiments of the inventive concept are not limited thereto. For example, one device may perform the roles of a plurality of devices in FIG. 2, and/or a plurality of devices may perform the role of a single device in FIG. 2.

First, the time correction unit 1262 may receive a temperature profile and a heater profile in operation S100. Here, the temperature profile may be a temperature profile of the dielectric window 1152, and the heater profile may be an operating profile of the second heater power source 1250. For example, the temperature profile may include a temperature measurement value of the dielectric window 1152 and/or a set temperature value of the dielectric window 1152. For example, the heater profile may include an operating value and/or a setting value of the second heater power source 1250. For example, the time correction unit 1262 may receive a temperature profile and a heater profile of each of a plurality of processes.

As described above, the upper heater 1153 heats the dielectric window 1152 in an air-heating method, and a temporal inconsistency between the operation of the second heater power source 1250 and an increase in the temperature of the dielectric window 1152 may occur (for example, a temporal offset, that is, a time difference or the like). The temperature profile and the heater profile may be relevant to each other and may form a pair. Accordingly, the plasma processing method according to an embodiment may provide a method of reducing process distribution for different processing of the wafer 90 by receiving and combining the temperature profile and the heater profile.

In addition, the time correction unit 1262 may receive data (i.e., process time data) about the time of a previous process (e.g., a previous process). The time of a process performed in the plasma processing apparatus 10 may be variously changed according to an operation. Accordingly, to extend and/or reduce the temperature profile and the heater profile according to the process time, the time correction unit 1262 may receive process time data of the previous process. When the time correction unit 1262 receives process time data of the previous process, the plasma processing method according to an embodiment may be performed while the process time is the latest. For example, the time correction unit 1262 may receive process time data of the previous process. In this case, the plasma processing time according to an embodiment may be performed while the process time is the latest.

Thereafter, the temperature profile and the heater profile may be combined to generate a combination profile in operation S200. Here, the combination profile may be a profile for controlling the second heater power source 1250. As will be described below, the combination profile may be generated by combining a first heater profile and a second heater profile. For example, the first heater profile may include an influence on the disturbance due to plasma arranged in the processing room 1172. The temperature of the dielectric window 1152 may be changed by the plasma arranged in the processing room 1172. The second heater profile may be a profile for reducing the difference between the temperature profile and a temperature measurement value. A method of generating a combination profile is described in detail below with reference to FIG. 4 and FIG. 2 together.

FIG. 4 is a flowchart illustrating a method of generating a combination profile, according to an embodiment. The description is made with reference to FIGS. 2 and 4 together.

Referring to FIG. 4, first, the time correction unit 1262 may calculate a first heater profile. For example, the time correction unit 1262 may modify the time domain of each of the received temperature profile and/or the heater profile based on the process time data.

When the length of the time domain of the process time data is greater than the length of the time domain of each of the temperature profile and/or the heater profile, the length of the time domain of each of the temperature profile and/or the heater profile may be extended. For example, the waveform of the temperature profile and/or the heater profile may be maintained, and the length of the time domain of the temperature profile and/or the heater profile may be extended according to the length of the time domain of the process time data. In another embodiment, the length of the time domain of the temperature profile and/or the heater profile may be extended by assuming that the last value of the temperature profile and/or the heater profile is maintained.

Conversely, when the length of the time domain of the process time data is less than the length of the time domain of each of the temperature profile and/or the heater profile, the length of the time domain of each of the temperature profile and/or the heater profile may be reduced. For example, the waveform of the temperature profile and/or the heater profile may be maintained, and the length of the time domain of the temperature profile and/or the heater profile may be reduced according to the length of the time domain of the process time data. In another embodiment, the length of the time domain of the temperature profile and/or the heater profile may be reduced by taking only a portion of the temperature profile and/or the heater profile according to the length of the time domain of the process time data. For example, when the time domain of the process time data is [0, t1], and the time domain of the temperature profile and/or the heater profile is [0, t2 (wherein t1<t2)], only the [0, t1] range value of each of the temperature profile and/or the heater profile may be taken.

When the length of the time domain of the process time data is equal to the length of the time domain of each of the temperature profile and/or the heater profile, modification on the length of the time domain for each of the temperature profile and/or the heater profile may not be performed.

A temperature profile with an adjusted length of time domain based on the process time data by the time correction unit 1262 may be referred to as a latest temperature profile, and a heater profile updated by the time correction unit 1262 may be referred to as a first heater profile.

Thereafter, the feedback control unit 1264 may calculate a second heater profile in operation S240. The feedback control unit 1264 may calculate the second heater profile based on the latest temperature profile, the temperature measurement value, and a feedback heater output value.

As described above, the latest temperature profile may be a temperature profile updated by the time correction unit 1262. The feedback control unit 1264 may receive the latest temperature profile from the time correction unit 1262. The time domain of the latest temperature profile may include the future (e.g., [t, t+a], wherein t means the current time).

The temperature measurement value may be a measurement value of the second temperature sensor 1159. The time domain of the temperature measurement value may include the past (e.g., [t−b, t], wherein t means the current time).

In addition, the feedback heater output value may be a heater output value obtained by deducting a heater output value considering plasma disturbance from a heater output value. The time domain of the feedback heater output value may include the past (e.g., [t−c, t], wherein t means the current time). For example, the time domain of the temperature measurement value may be different from the time domain of the feedback heater output value. In another embodiment, the time domain of the temperature measurement value may coincide with the time domain of the feedback heater output value.

The feedback control unit 1264 may correct an error between the temperature profile and the temperature measurement value. For example, the feedback control unit 1264 may calculate a second heater profile in a proportional-integral-derivative (PID) control method in an embodiment. In another embodiment, the feedback control unit 1264 may calculate the second heater profile in a model predictive control (MPC) method. However, embodiments of the inventive concept are not limited thereto, and the second heater profile may be calculated by using various techniques.

Thereafter, the summation unit 1266 may generate a combination profile based on the first heater profile and the second heater profile in operation S260. For example, the summation unit 1266 may generate a combination profile by summing the first heater profile and the second heater profile. In another embodiment, the summation unit 1266 may generate a combination profile by summing the first heater profile and the second heater profile to which weights have been applied. Accordingly, the summation unit 1266 may generate a combination profile based on the first heater profile considering the disturbance and the second heater profile that is irrelevant to the disturbance.

Referring to FIGS. 2 and 3 again, the confirmation unit 1268 may receive the combination profile and then generate a final profile from the combination profile in operation S300. The confirmation unit 1268 may compare the combination profile generated by the summation unit 1266 with a limit condition of the second heater power source 1250. When the combination profile does not violate the limit condition of the second heater power source 1250, the combination profile may be selected as the final profile. When the combination profile violates the limit condition of the second heater power source 1250, the confirmation unit 1268 may partially modify the combination profile to satisfy the limit condition of the second heater power source 1250 and then select the modified combination profile as the final profile. Here, the limit conditions may mean a condition including one or more of the constraints and boundaries in a system. For example, the limit condition may include an upper limit and a lower limit of an output value of the second heater power source 1250.

The plasma processing method according to an embodiment may generate a final profile with reduced process distribution by combining a temperature profile and a heater profile, which form a pair. In this process, the time correction unit 1262 may update the temperature profile and the heater profile, and the feedback control unit 1264 may correct an error between the temperature profile and the temperature measurement value. In addition, the summation unit 1266 may generate a combination profile by combining the first heater profile and the second heater profile, and the confirmation unit 1268 may check the combination profile based on the limit condition of the second heater power source 1250.

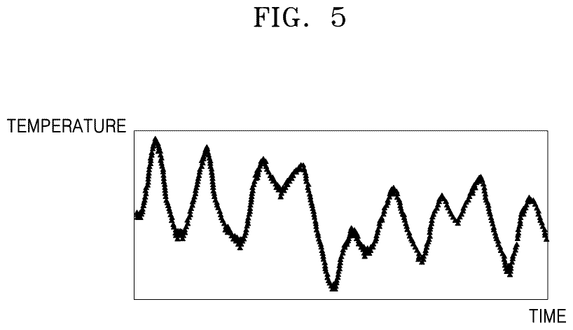

FIG. 5 is a graph showing a temperature profile according to an embodiment. As described above, the temperature profile may include the temperature measurement value measured by the second temperature sensor 1159. The horizontal axis of the graph represents time (arbitrary unit: a.u.), and the vertical axis of the graph represents temperature (a.u.). The description is made with reference to FIGS. 1 to 4 together.

Referring to FIG. 5, the temperature of the dielectric window 1152 may not be maintained at a constant value and may be changed over time. That is, as a process is performed inside the plasma processing apparatus 10, the temperature of the dielectric window 1152 may be continuously changed without being maintained at a constant value. That is, the temperature of the dielectric window 1152 may remain transient. Accordingly, the main controller 1260 may control the temperature of the dielectric window 1152 by receiving the temperature profile and the heater profile.

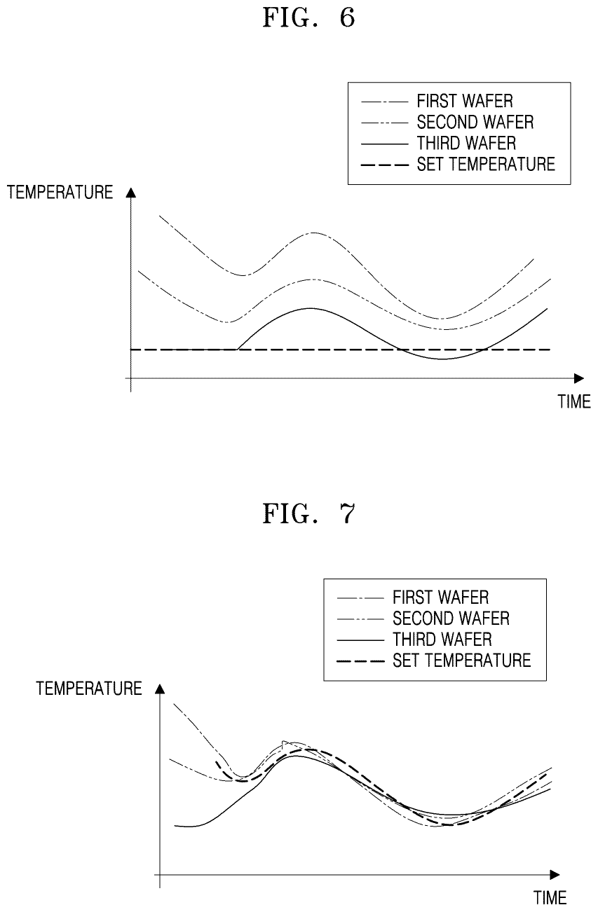

FIG. 6 is a graph showing the temperature for each wafer according to a comparative example. FIG. 7 is a graph showing the temperature for each wafer according to an embodiment. In FIGS. 6 and 7, the horizontal axis of the graph represents time (a.u.), and the vertical axis of the graph represents temperature (a.u.). In FIGS. 6 and 7, the dotted line shows a set temperature value. The description is made with reference to FIGS. 1 to 5 together.

Referring to FIGS. 6 and 7, the set temperature value in the comparative example may be constant. Conversely, in the embodiment, the set temperature value may be changed without being constant. For example, in the comparative example, a regulation control method of controlling a process temperature by using the constant set temperature value as a reference may be used. Conversely, in the embodiment, a plasma process may be controlled by using a temperature profile and a heater profile. In addition, in the embodiment, the plasma process may be controlled by using a temperature profile of which the value changes over time.

A difference in temperature in the first to third wafers of the comparative example of FIG. 6 may be greater than a difference in temperature in the first to third wafers of the embodiment of FIG. 7. Accordingly, in the embodiment, process distribution for each wafer 90 may be reduced as compared to the comparative example. Accordingly, the plasma processing method according to an embodiment may process the wafer 90 with high reliability.

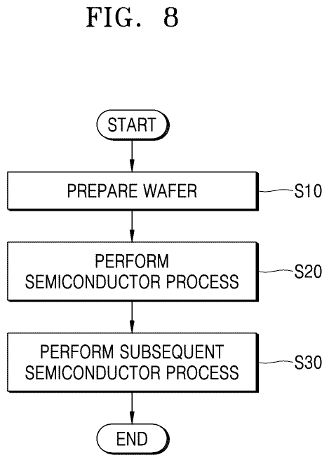

FIG. 8 is a flowchart illustrating a wafer processing method according to an embodiment. The description is made with reference to FIGS. 1 to 4 together.

Referring to FIG. 8, first, the wafer 90 may be prepared in operation S10. The wafer 90 may include, for example, a bare wafer on which one or more semiconductor processes are performed or the semiconductor process is not performed.

Thereafter, a semiconductor process may be performed on the wafer 90 in operation S20. An oxidation process, a photo process, a deposition process, an etching process, an ion process, and/or a cleaning process may be performed on the wafer 90.

Operation S20 of performing the semiconductor process may include operation S100 of receiving a temperature profile and a heater profile, operation S200 of calculating a combination profile, and operation S300 of outputting a final heater profile of FIG. 3. In addition, operation S200 of calculating the combination profile may include operation S220 of calculating a first heater profile, operation S240 of calculating a second heater profile, and operation S260 of combining the first heater profile and the second heater profile.

Thereafter, a subsequent semiconductor process may be performed on the wafer 90 in operation S30. The subsequent semiconductor process on the wafer 90 may include various processes. For example, the subsequent semiconductor process may include an oxidation process, a photo process, a deposition process, an etching process, an ion process, and/or a cleaning process, or the like. In addition, the subsequent semiconductor process may include a singulation process of individualizing the wafer 90 into each semiconductor chip, a test process of testing semiconductor chips, and/or a packaging process of packaging the semiconductor chips. A semiconductor device may be completed through the subsequent semiconductor process on the wafer 90.

While the inventive concept has been particularly shown and described with reference to embodiments thereof, it will be understood that various changes in form and details may be made therein without departing from the spirit and scope of the following claims.

What is claimed is:

1. A wafer processing method comprising:
performing a process on the wafer;
wherein the performing of the process on the wafer comprises:
receiving a temperature profile and a heater profile, the temperature profile and the heater profile forming a pair with each other;
calculating a combination profile based on the temperature profile and the heater profile;
outputting a final profile based on the combination profile; and
performing wafer processing by using a plasma based on the final profile.

2. The wafer processing method of claim 1, wherein the heater profile comprises a first heater profile and a second heater profile.

3. The wafer processing method of claim 2, wherein the calculating of the combination profile comprises calculating the combination profile by summing the first heater profile and the second heater profile, or
calculating the combination profile by summing the first heater profile and the second heater profile to which weights have been applied.

4. The wafer processing method of claim 1, wherein the calculating of the combination profile is performed by feedback control that compensates for an error between the temperature profile and a temperature measurement value.

5. The wafer processing method of claim 1, wherein the calculating of the combination profile comprises updating a length of a time domain of each of the temperature profile and the heater profile based on previous process time data.

6. The wafer processing method of claim 1, wherein the outputting of the final profile is performed by comparing the combination profile with a limit condition of a heater power source.

7. The wafer processing method of claim 1, wherein the temperature profile comprises a temperature profile of a dielectric window,
wherein the heater profile comprises an operating profile of a heat power source, and
wherein the dielectric window and a heater electrically connected to a heater power source are spaced apart from each other.

8. A wafer processing method comprising:
performing a process on the wafer;
wherein the performing of the process on the wafer comprises:
receiving a temperature profile and a heater profile, the temperature profile and the heater profile forming a pair with each other;
calculating a first heater profile and a second heater profile based on the temperature profile and the heater profile;
calculating a combination profile based on the first heater profile and the second heater profile;
outputting a final profile based on the combination profile; and
performing wafer processing by using a plasma based on the final profile,
wherein the second heater profile is calculated based on feedback control.

9. The wafer processing method of claim 8, further comprising receiving previous process time data.

10. The wafer processing method of claim 9, further comprising changing a length of a time domain of each of the temperature profile and the heater profile based on a length of a time domain of the previous process time data.

11. The wafer processing method of claim 10, wherein a waveform of the heater profile before changing the length of the time domain is the same as a waveform of the heater profile after changing the length of the time domain.

12. The wafer processing method of claim 10, wherein the length of the time domain of the previous process time data is the same as a length of a time domain of the first heater profile.

13. The wafer processing method of claim 8, wherein the second heater profile is calculated based on a latest temperature profile having a future time domain, a temperature measurement value having a past time domain, and a feedback heater output value having the past time domain.

14. The wafer processing method of claim 8, wherein the temperature profile comprises a temperature profile of a dielectric window,
wherein the heater profile comprises an operating profile of a heater power source, and
wherein a heater electrically connected to the heater power source heats the dielectric window in an air-heating method.

15. The wafer processing method of claim 8, wherein a value of the temperature profile changes over time.

16. A wafer processing method comprising:
preparing a wafer; and
performing a process on the wafer;
wherein the performing of the process on the wafer comprises:
receiving a temperature profile and a heater profile, the temperature profile and the heater profile forming a pair with each other;
calculating a combination profile based on the temperature profile and the heater profile; and
outputting a final profile based on the combination profile.

17. The wafer processing method of claim 16, wherein the heater profile comprises a first heater profile and a second heater profile, and
wherein the second heater profile is calculated based on feedback control.

18. The wafer processing method of claim 17, wherein the calculating of the second heater profile is calculated based on a temperature measurement value comprising a past time domain, a feedback heater output value comprising the past time domain, and a latest temperature profile comprising a future time domain.

19. The wafer processing method of claim 16, wherein the temperature profile comprises a temperature profile of a dielectric window,
wherein the heater profile comprises an operating profile of a heater power source, and
wherein the dielectric window and a heater electrically connected to the heater power source are spaced apart from each other.

20. The wafer processing method of claim 16, wherein the process comprises an etching process; and
wherein the method further comprises:
performing a subsequent process on the wafer.
